(19) United States
(12) Patent Application Publication
(10) Pub. No.: US 2025/0149448 A1
(43) Pub. Date: May 8, 2025

(54) SEMICONDUCTOR DEVICE WITH BACKSIDE VIAS AND METHOD OF FABRICATION THEREOF

(71) Applicant: Taiwan Semiconductor Manufacturing Company, Ltd., Hsin-Chu (TW)

(72) Inventor: Chen-Ming Lee, Taoyuan County (TW)

(21) Appl. No.: 18/503,666

(22) Filed: Nov. 7, 2023

(51) Int. Cl. H01L 23/528; H01L 29/06; H01L 29/40; H01L 29/417; H01L 29/423; H01L 29/66; H01L 29/775

(52) U.S. Cl. CPC H01L 23/5286; H10D 30/014; H10D 30/43; H10D 30/6729; H10D 30/6735; H10D 62/121; H10D 64/01

(57) ABSTRACT

A method includes providing a structure having a substrate, a fin-shape base protruding from the substrate, an isolation structure on sidewalls of the fin-shape base, and an epitaxial feature over the fin-shape base. The substrate is at the backside of the structure and the epitaxial feature is at the frontside of the structure. The method also includes recessing the substrate from the backside of the structure to expose a bottom surface of the isolation structure, forming a backside dielectric layer covering the isolation structure, depositing an etch stop layer on a bottom surface of the backside dielectric layer, forming an opening in the etch stop layer, wherein the opening exposes the fin-shape base from the backside of the structure, etching the fin-shape base from the opening to expose the epitaxial feature, and forming a backside conductive feature in the opening and in physical contact with the epitaxial feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Conventionally, ICs are built in a stacked-up fashion, having transistors at the lowest level and interconnect (vias and wires) on top of the transistors to provide connectivity to the transistors. Power rails (such as metal lines for voltage sources and ground planes) are also above the transistors and may be part of the interconnect. As the integrated circuits continue to scale down, so do the power rails. This inevitably leads to increased voltage drop across the power rails, as well as increased power consumption of the integrated circuits. Other than power rails, signal lines may also suffer from such scaling down, such as the ever-reduced signal line pitches that inevitably leads to increased parasitic capacitance and reduced circuit speed. Therefore, although existing approaches in semiconductor fabrication have been generally adequate for their intended purposes, they have not been entirely satisfactory in all respects. One area of interest is how to form backside interconnect structure, including power rails and/or signal lines, and vias on the backside of an IC, with reduced resistance and parasitic capacitance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method of forming a semiconductor device, in accordance with some embodiments of the present disclosure.

FIG. 2 illustrates a top view of a portion of a semiconductor device, in accordance with some embodiments of the present disclosure.

FIGS. 3A, 4A, 5A, 6A, 7A, 8A, 9A, 10A, 11A, 12A, 13A, 14A, 15A, 16A, and 17A illustrate cross-sectional views along the A-A line of the portion of the semiconductor device in FIG. 2 during fabrication processes according to the method of FIG. 1, in accordance with some embodiments of the present disclosure.

FIGS. 3B, 4B, 5B, 6B, 7B, 8B, 9B, 10B, 11B, 12B, 13B, 14B, 15B, 16B, and 17B illustrate cross-sectional views along the B-B line of the portion of the semiconductor device in FIG. 2 during fabrication processes according to the method of FIG. 1, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term encompasses numbers that are within certain variations (such as +/−10% or other variations) of the number described, in accordance with the knowledge of the skilled in the art in view of the specific technology disclosed herein, unless otherwise specified. For example, the term “about 5 nm” may encompass the dimension range from 4.5 nm to 5.5 nm, etc.

This application generally relates to semiconductor structures and fabrication processes, and more particularly to integrate circuit (IC) chips having transistors with backside interconnect structure that includes backside metal lines and backside vias.

An object of the present disclosure includes providing an interconnect structure (e.g., power rails and/or signal lines) on a backside of a semiconductor device containing transistors in addition to an interconnect structure (which includes power rails and signal lines) on a frontside of the semiconductor device. This configuration increases the number of metal tracks available in the semiconductor device for directly connecting to source/drain regions and/or gates of the transistors. It also increases the gate density for greater device integration than existing structures without the backside interconnect structure. The backside metal lines may have wider dimension and larger pitch than the first level metal (MO) tracks on the frontside of the structure, which beneficially reduces the line resistance and parasitic capacitance. The present disclosure also provides a backside via for connecting the backside power rails and/or backside signal lines to source/drain features formed on the frontside. The backside via is formed in a self-aligned manner such that isolation structures (e.g., shallow trench isolation (STI) structure and/or deep trench isolation (DTI) structure) would not suffer from significant etching loss during the formation of the backside via, which prevents accidental shorts between the backside via and a metal gate stack due to gate protrusion.

The details of the structure and fabrication methods of the present disclosure are described below in conjunction with the accompanied drawings, which illustrate a process of making multi-gate transistors, particularly gate-all-around (GAA) transistors, according to some embodiments. A GAA transistor refers to a transistor having vertically-stacked horizontally-oriented channel members, such as in the form of nanowires and/or nanosheets. GAA transistors are promising candidates to take CMOS to the next stage of the roadmap due to their better gate control ability, lower leakage current, and fully field effect transistor (FET) layout compatibility. For the purposes of simplicity, the present disclosure uses GAA transistors as an example. Those of ordinary skill in the art should appreciate that they may readily use the present disclosure as a basis for designing or modifying other processes and structures (such as FinFET transistors) for carrying out the same purposes and/or achieving the same advantages of the embodiments introduced herein.

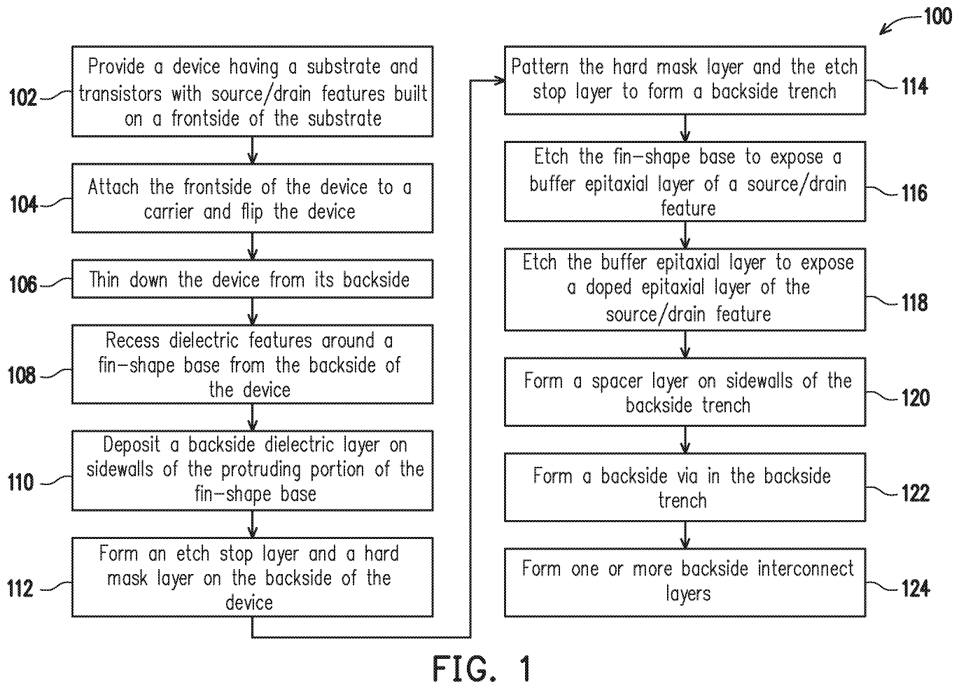

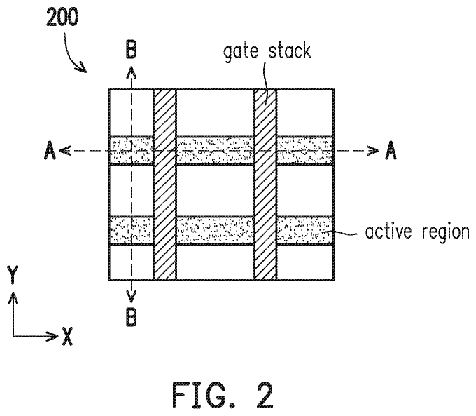

FIG. 1 shows a flow chart of a method 100 for fabricating a semiconductor device with backside metal lines and backside vias, according to some embodiments of the present disclosure. The method 100 is described below in conjunction with FIGS. 2 through 17B that illustrate various top and cross-sectional views of a semiconductor device (or device) 200 at various steps of fabrication according to the method 100, in accordance with some embodiments. Additional processing is contemplated by the present disclosure. Additional operations can be provided before, during, and after method 100, and some of the operations described can be moved, replaced, or eliminated for additional embodiments of the method 100.

In some embodiments, the device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof.

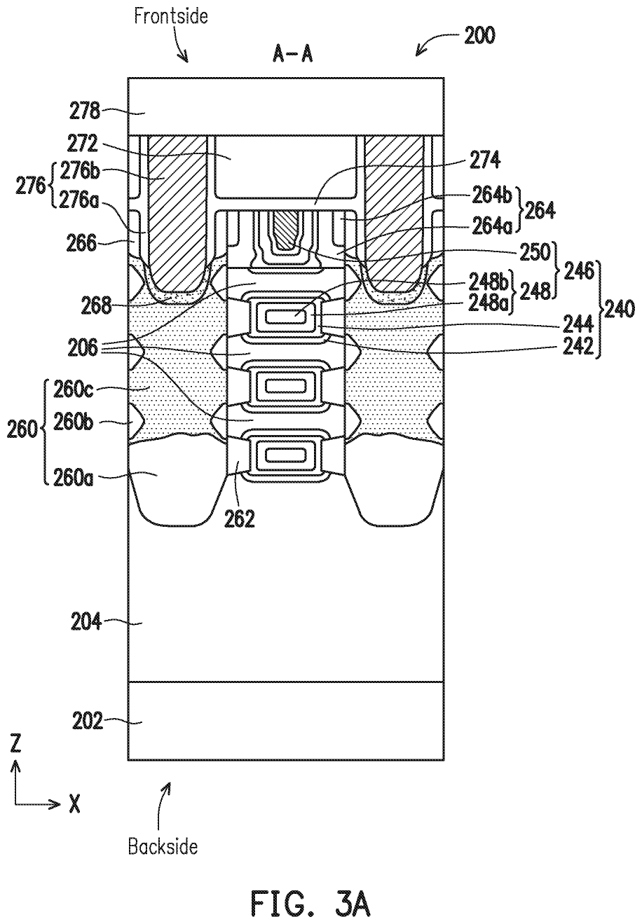

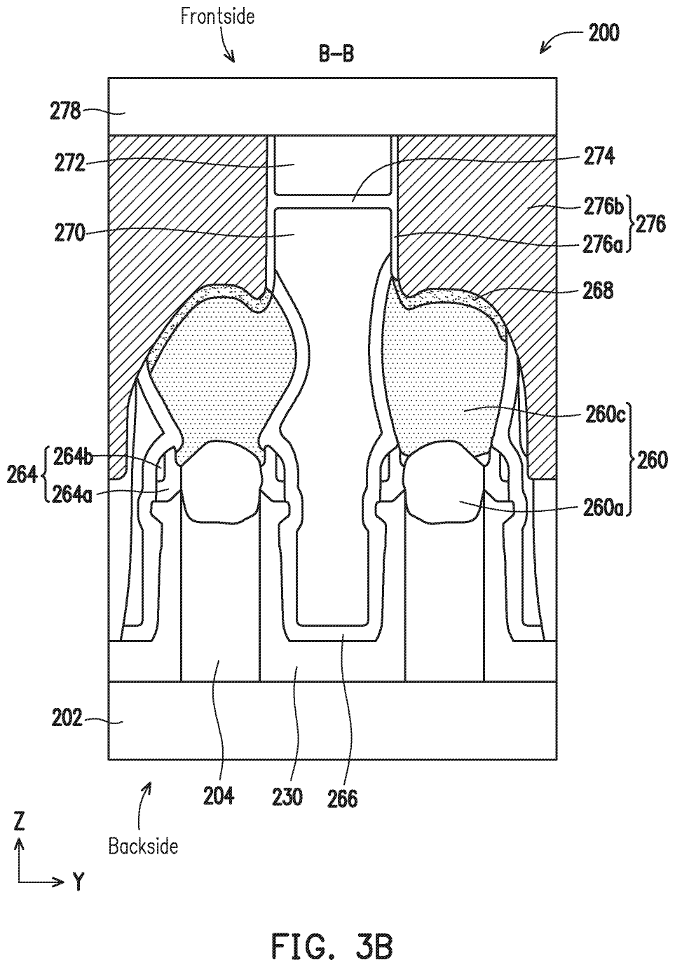

FIG. 2 and FIGS. 3A-17B have been simplified for the sake of clarity to better understand the inventive concepts of the present disclosure. Additional features can be added in the device 200, and some of the features described below can be replaced, modified, or eliminated in other embodiments of the device 200. FIG. 2 illustrates a top view of the device 200, in which multiple active regions are oriented lengthwise along the X-direction, and multiple gate stacks are oriented lengthwise along the Y-direction. At intersections of the active regions and the gate stacks, transistors are formed. An active region for a transistor refers to the area where a source region, a drain region, and a channel region under a gate structure of the transistor are formed. An active region is also referred to as an “oxide-definition (OD) region” in the context. In the context of a GAA transistor, an active region includes elongated nanostructures (also referred to as channel members or channel layers) vertically stacked in channel regions defined in the active region and above a fin-shape base. The fin-shape base protrudes upwardly out of a substrate. Source/drain features are formed in source/drain regions defined in the active region and over the fin-shape base. The source/drain features abut two opposing ends of the nanostructures. The source/drain features may include one or more epitaxial layers that are epitaxially grown above the fin-shape base. Source/drain region(s) may refer to a source or a drain, individually or collectively dependent upon the context. FIGS. 3A-17B illustrate cross-sectional views of the device 200, in portion, along the A-A line and the B-B line in FIG. 2, respectively. Particularly, along the A-A line is a cut in the lengthwise direction of active regions (X-direction), along the B-B line is a cut into the source/drain regions of transistors and are parallel to gate stacks of the transistors (Y-direction).

Referring to FIGS. 1 and 3A-3B, at operation 102, the method 100 provides (or receives) a device 200. The device 200 includes a substrate 202 at its backside and various elements built on the front surface of the substrate 202. These elements include an isolation structure 230 over the substrate 202, fin-shape bases 204 extending from the substrate 202 and adjacent to the isolation structure 230, and source/drain features 260 over the fin-shape bases 204 in the source/drain regions. The device 200 further includes nanostructures 206 vertically stacked and suspended over the fin-shape base 204, and a gate stack 240 between the two source/drain features 260 and wrapping around each of the nanostructures 206. The nanostructures 206 connect two source/drain features 260 and function as channel layers of the GAA transistors.

The device 200 further includes inner spacers 262 between the source/drain features 260 and the gate stacks 240, a (outer) gate spacer 264 over sidewalls of the gate stack 240, a contact etch stop layer (CESL) 266 adjacent to the gate spacer 264 and over the source/drain features 260 and the isolation structure 230, a first inter-layer dielectric (ILD) layer 270 over the CESL 269, a second ILD layer 272 over the first ILD layer 270, and an etch stop layer (ESL) 274 interposing the first ILD layer 270 and the second ILD layer 272. Over the source/drain features 260, the device 200 further includes silicide features 268 and source/drain contacts 276. The device 200 further includes one or more interconnect layers 278 with wires and vias (not shown) embedded in dielectric layers. The wires and vias in the interconnect layers 278 connect gate, source, and drain electrodes of various transistors, as well as other circuits in the device 200, to form an integrated circuit in part or in whole. The device 200 may further include passivation layers, adhesion layers, and/or other layers built on the frontside of the device 200. These layers and the one or more interconnect layers are collectively denoted with the label 278.

In an embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In an alternative embodiment, substrate 202 is a semiconductor-on-insulator substrate, such as a silicon-on-insulator (SOI) substrate, a silicon germanium-on-insulator (SGOI) substrate, or a germanium-on-insulator (GOI) substrate.

In embodiments, the fin-shape bases 204 may include silicon, silicon germanium, germanium, or other suitable semiconductor, and may be doped n-type or p-type dopants. The fin-shape bases 204 may be patterned by any suitable method. For example, the fin-shape bases 204 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used as a masking element for patterning the fin-shape bases 204. For example, the masking element may be used for etching recesses into semiconductor layers over or in the substrate 202, leaving the fin-shape bases 204 on the substrate 202. The etching process may include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. Numerous other embodiments of methods to form the fin-shape bases 204 may be suitable.

The isolation structure 230 may include silicon oxide, silicon nitride, silicon oxynitride, other suitable isolation material (for example, including silicon, oxygen, nitrogen, carbon, or other suitable isolation constituent), or combinations thereof. The isolation structure 230 can include different structures, such as shallow trench isolation (STI) features and/or deep trench isolation (DTI) features. In an embodiment, the isolation structure 230 can be formed by filling the trenches between fin-shape bases 204 with insulator material (for example, by using a CVD process or a spin-on glass process), performing a chemical mechanical polishing (CMP) process to remove excessive insulator material and/or planarize a top surface of the insulator material layer, and etching back the insulator material layer to form the isolation structure 230. In some embodiments, the isolation structure 230 include multiple dielectric layers, such as a silicon nitride layer disposed over a thermal oxide liner layer.

The nanostructures 206 may include a semiconductor material suitable for transistor channels, such as silicon, silicon germanium, or other semiconductor material(s). The nanostructures 206 may be in the shape of rods, bars, sheets, or other shapes in various embodiments. In an embodiment, the nanostructures 206 are initially part of a stack of semiconductor layers that include the nanostructures 206 and other sacrificial semiconductor layers alternately stacked layer-by-layer. The sacrificial semiconductor layers and the nanostructures 206 include different material compositions (such as different semiconductor materials, different constituent atomic percentages, and/or different constituent weight percentages) to achieve etching selectivity. During a gate replacement process to form the gate stacks 240, the sacrificial semiconductor layers are selectively removed, leaving the nanostructures 206 suspended over the fin-shape bases 204. It is noted that three (3) nanostructures 206 are vertically stacked in the illustrated embodiment, which is for illustrative purposes only and not intended to be limiting beyond what is specifically recited in the claims. It can be appreciated that any number of nanostructures can be formed, depending on device performance needs. In some embodiments, the number of nanostructures 206 vertically stacked is between (including) 2 and 10.

The source/drain features 260 may be a multi-layer structure. For example, the source/drain features 260 may include a buffer epitaxial layer 260a, a first doped epitaxial layer 260b, and a second doped epitaxial layer 260c. By way of example, epitaxial growth of the buffer epitaxial layer 260a may be performed by vapor-phase epitaxy (VPE), ultra-high vacuum CVD (UHV-CVD), molecular beam epitaxy (MBE), and/or other suitable processes. In some embodiments, the buffer epitaxial layer 260a includes the same material as the substrate 202, such as silicon (Si). In some alternative embodiments, the buffer epitaxial layer 260a includes a different semiconductor material than the Si substrate 202, such as SiGe, SiSn, or other suitable semiconductor material. In some embodiments, the buffer epitaxial layer 260a is dopant-free, where for example, no intentional doping is performed during the epitaxial growth process. Therefore, the buffer epitaxial layer 260a may also be referred to as undoped epitaxial layer 260a. As a comparison, in one instance, the substrate 202 is lightly doped and has a higher doping concentration than the buffer epitaxial layer 260a. The buffer epitaxial layer 260a provides a high resistance path from the source/drain regions to the semiconductor substrate, such that the leakage current in the semiconductor substrate (i.e., through the fin-shape base 204) is suppressed.

The first doped epitaxial layer 260b may make contact with the lateral ends of the nanostructures 206. The second doped epitaxial layer 260c covers the first doped epitaxial layer 262a and is in contact with the inner spacers 262. In an embodiment, forming the doped epitaxial layers 260b and 260c includes epitaxially growing the semiconductor layers by an MBE process, a chemical vapor deposition process, and/or other suitable epitaxial growth processes. In a further embodiment, the doped epitaxial layers 260b and 260c are in-situ or ex-situ doped with dopant(s). For example, the doped epitaxial layers 260b and 260c may include silicon doped with phosphorous or arsenic for n-type devices. Alternatively, the doped epitaxial layers 260b and 260c may include silicon germanium doped with boron for p-type devices. In some embodiments, the first doped epitaxial layer 260b includes the same dopant species as the second doped epitaxial layer 260c. In some embodiments, the first doped epitaxial layer 260b includes a different dopant species from the second doped epitaxial layer 260c. For example, the first doped epitaxial layer 260b may include silicon doped with arsenic, and the second doped epitaxial layer 260c may include silicon doped with phosphorous. In various embodiments, the dopant concentration is increasingly grading from the first doped epitaxial layer 260b to the second doped epitaxial layer 260c, which facilitate subsequent silicidation process (e.g., nickel silicide formation) for landing source/drain contacts on the source/drain features. Further, the first doped epitaxial layer 260b and the second doped epitaxial layer 260c may include a constant distribution of dopant concentration individually in some embodiments. For example, the second doped epitaxial layer 260c includes a constant distribution where the dopant concentration is constant from its bottommost to its topmost but larger than that of the first doped epitaxial layer 260b. The second doped epitaxial layer 260c may have a lower resistivity than the first doped epitaxial layer 260b, and the first doped epitaxial layer 260b may have a lower resistivity than the undoped epitaxial layer 260a.

The inner spacers 262 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the inner spacers 262 include a low-k dielectric material, such as those described herein. The inner spacers 262 may be formed by deposition and etching processes. For example, after source/drain trenches are etched and before the source/drain features 260 are epitaxially grown from the source/drain trenches, an etch process may be used to recess the sacrificial semiconductor layers between the adjacent nanostructures 206 to form gaps vertically between the adjacent nanostructures 206. Then, one or more dielectric materials are deposited (using CVD or ALD for example) to fill the gaps. Another etching process is performed to remove the dielectric materials outside the gaps, thereby forming the inner spacers 262.

The gate stacks 240 may include an interfacial layer 242 formed on exposed surfaces of the nanostructures 206, a high-k dielectric layer 244 formed over the interfacial layer 242, and a gate electrode layer 246 formed over the high-k dielectric layer 244. The interfacial layer 242 may include silicon dioxide, silicon oxynitride, or other suitable materials. The interfacial layer 242 may be formed by chemical oxidation, thermal oxidation, atomic layer deposition (ALD), chemical vapor deposition (CVD), and/or other suitable methods. The high-k dielectric layer 244 may include a high-k dielectric material such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9). The high-k dielectric layer 244 may be formed by ALD, CVD, metal-organic CVD (MOCVD), PVD, thermal oxidation, and/or other suitable methods. In some embodiments, the gate electrode layer 246 includes a work function layer 248 that is an n-type or a p-type work function layer and a metal fill layer 250 over the work function layer 248. For example, an n-type work function layer may comprise a metal with sufficiently low effective work function, and a p-type work function layer may comprise a metal with a sufficiently large effective work function. In some embodiments, the work function layer 248 may include a multi-layer structure, such as a first work function layer 248a and a second work function layer 248b. For example, the first work function layer 248a may comprise a metal such as titanium, aluminum, tantalum carbide, tantalum carbide nitride, tantalum silicon nitride, or combinations thereof, and the second work function layer 248b may comprise a metal such as titanium nitride, tantalum nitride, ruthenium, molybdenum, tungsten, platinum, or combinations thereof. For example, the metal fill layer 250 may include aluminum, tungsten, cobalt, copper, and/or other suitable materials. The gate electrode layer 246 may be formed by CVD. PVD, plating, and/or other suitable processes. Since the gate stacks 240 include a high-k dielectric layer and metal layer(s), it is also referred to as high-k metal gates.

The gate spacers 264 may include a dielectric material such as a dielectric material including silicon, oxygen, carbon, nitrogen, other suitable material, or combinations thereof (e.g., silicon oxide, silicon nitride, silicon oxynitride (SiON), silicon carbide, silicon carbon nitride (SiCN), silicon oxycarbide (SiOC), silicon oxycarbon nitride (SiOCN)). In embodiments, the gate spacer 264 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s). For example, a dielectric layer including silicon and nitrogen, such as a silicon nitride layer, can be deposited over a dummy gate stack (which is subsequently replaced by the high-k metal gate 240) and subsequently etched (e.g., anisotropically etched) to form the gate spacers 264. In some embodiments, the gate spacers 264 include a multi-layer structure, such as a first dielectric layer 264a that includes silicon nitride and a second dielectric layer 264b that includes silicon oxide. In some embodiments, more than one set of spacers, such as seal spacers, offset spacers, sacrificial spacers, dummy spacers, and/or main spacers, are formed adjacent to the gate stack 240. As shown in FIG. 3B, the gate spacers 264 may extend to source/drain regions as fin spacers which are disposed on sidewalls of the source/drain features 260 and/or fin-shape bases 204.

The CESL 266 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The first ILD layer 270 may comprise tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 270 may be formed by PE-CVD (plasma enhanced CVD), F-CVD (flowable CVD), or other suitable methods. The second ILD layer 272 is deposited over the first ILD layer 270. The second ILD layer 272 may be made by similar material utilized to form the first ILD layer 270. In furtherance of some embodiments, the first ILD layer 270 and the second ILD layer 272 may include the same or different material compositions. The etch stop layer 274 may be formed of a dielectric material having a different etch selectivity from adjacent layers, for example, the first ILD layer 270 and the second ILD layer 272. The etch stop layer 274 may comprise silicon nitride, silicon carbon nitride, silicon carbon oxide, carbon nitride, the like, or a combination thereof, and may be deposited by chemical vapor deposition (CVD), plasma enhanced CVD (PECVD), atomic layer deposition (ALD), or another deposition technique.

The silicide features 268 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The source/drain contacts 276 may include a conductive barrier layer 276a and a metal fill layer 276b over the conductive barrier layer 276a. The conductive barrier layer 276a may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer 276b may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer 276a is omitted in the source/drain contacts 276.

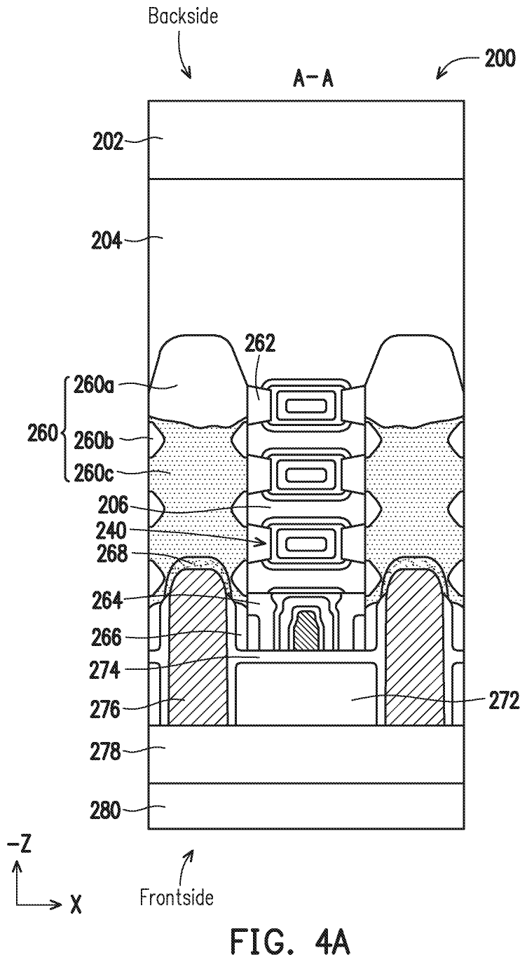

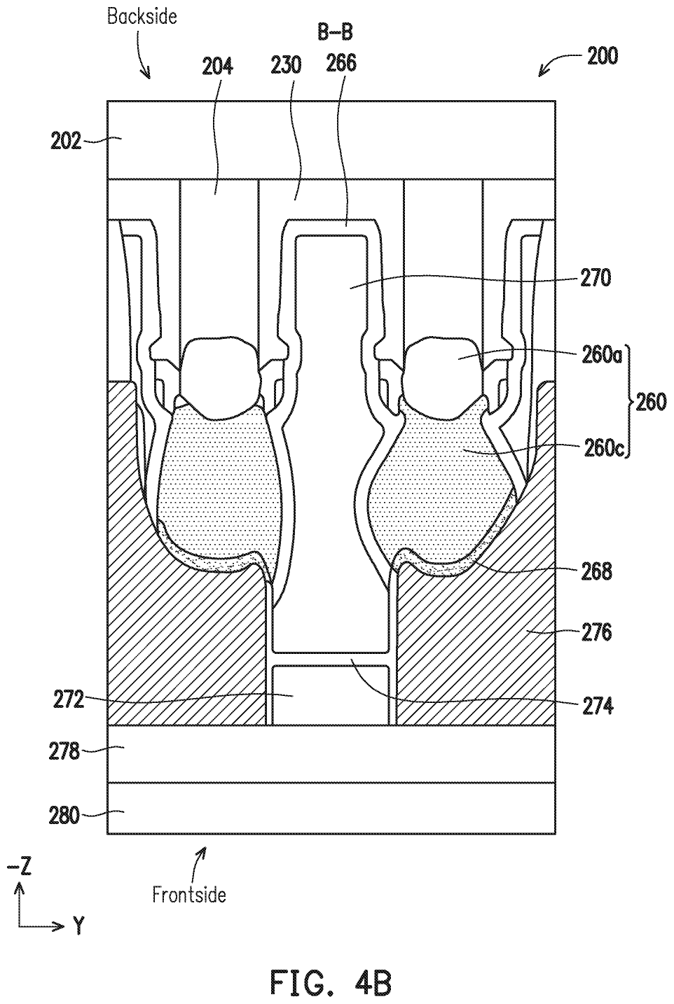

Referring to FIGS. 1 and 4A-4B, at operation 104, the method 100 attaches the frontside of the device 200 to a carrier 280 and flips the device 200 upside down. This makes the device 200 accessible from the backside of the device 200 for further processing. The operation 104 may use any suitable attaching processes, such as direct bonding, hybrid bonding, using adhesive, or other bonding methods. The operation 104 may further include alignment, annealing, and/or other processes. The carrier 280 may be a silicon wafer in some embodiments. In FIGS. 4A-17B, the “Z” direction points from the backside of the device 200 to the frontside of the device 200, while the “−Z” direction points from the frontside of the device 200 to the backside of the device 200.

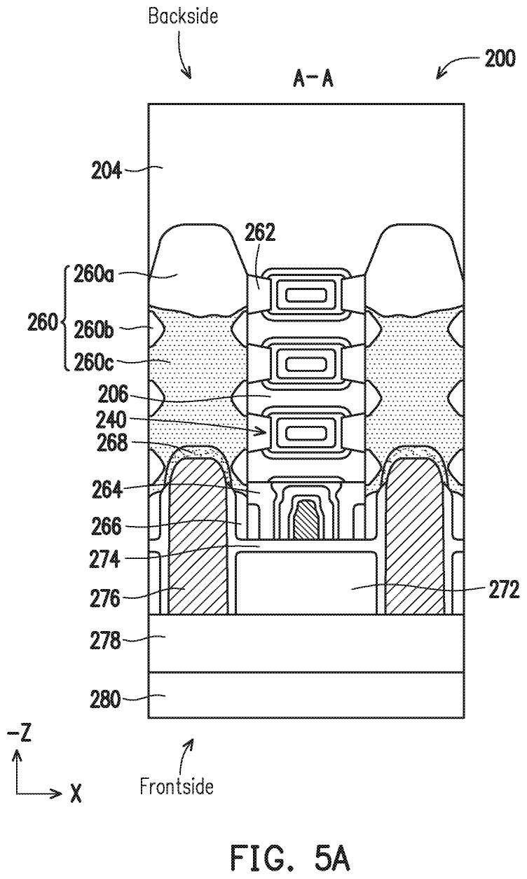

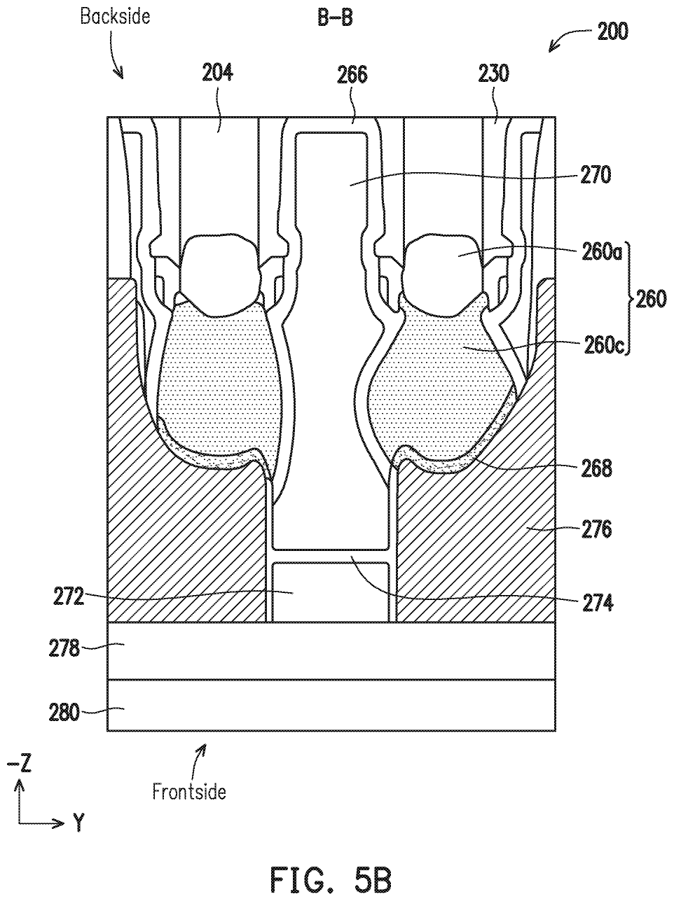

Referring to FIGS. 1 and 5A-5B, at operation 106, the method 100 thins down the device 200 from the backside of the device 200 until the fin-shape bases 204 and the isolation structure 230 are exposed from the backside of the device 200. The thinning process may include a mechanical grinding process and/or a chemical thinning process. A substantial amount of substrate material may be first removed from the substrate 202 during a mechanical grinding process. Afterwards, a chemical thinning process may apply an etching chemical to the backside of the substrate 202 to further thin down the substrate 202. In the illustrated embodiments, the CESL 266 may function as the thinning stop layer, such that the thinning process stops at the bottom surface of the CESL 266.

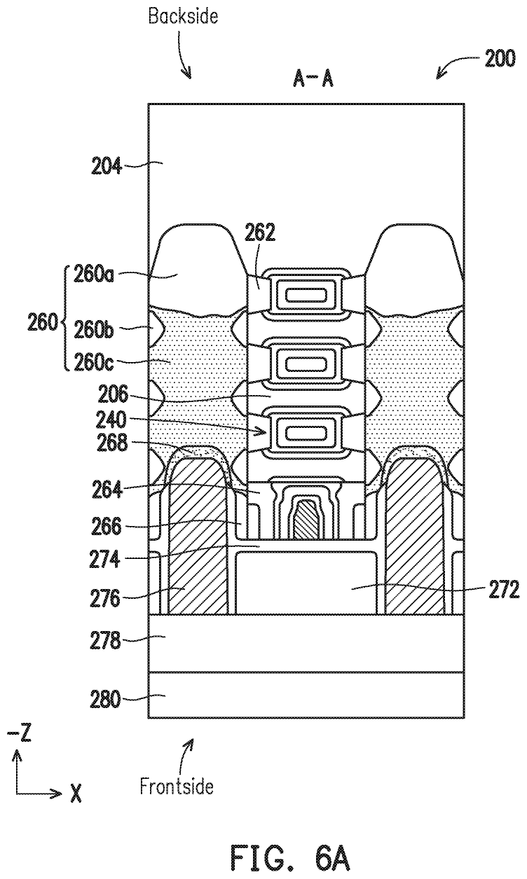

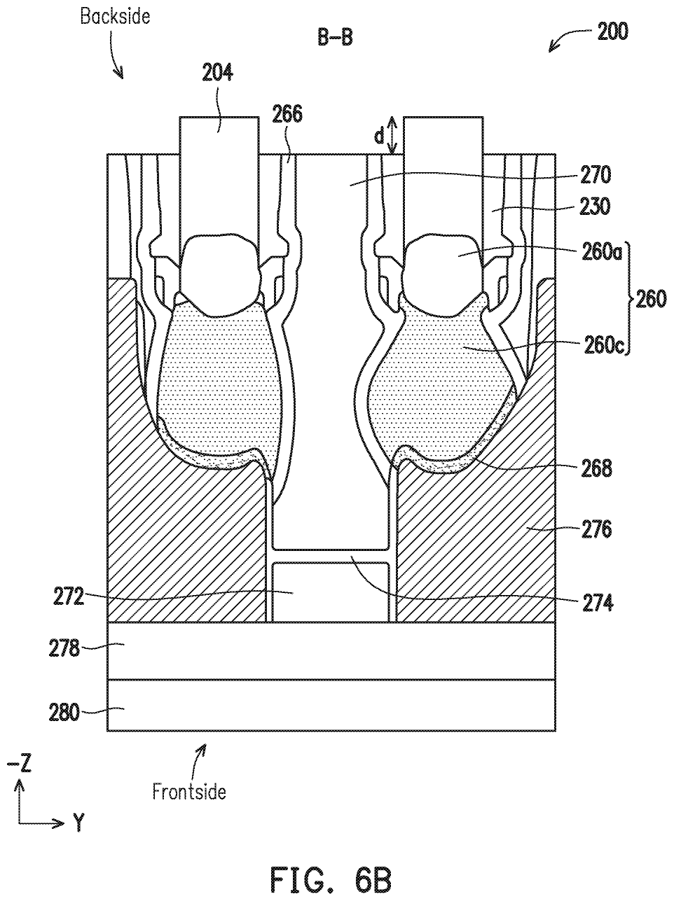

Referring to FIGS. 1 and 6A-6B, at operation 108, the method 100 applies an etching process that is tuned to be selective to the dielectric materials, such as the dielectric materials in the CESL 266, the isolation structure 230, and the first ILD layer 270, and with no (or minimal) etching to the semiconductor material in the fin-shape bases 204. The etching process can be a plasma dry etching, a chemical dry etching, an ashing process, a wet etching, or other suitable etching methods. For example, the plasma dry etching process may use conventional dry etchant for dielectric material such as C₄F₆ mixed with H₂ or O₂, the chemical dry etching process may use one or more chemicals such as H₂, the ashing process may use oxygen or hydrogen ashing, and the wet etching process may apply a hot SPM solution (a mixture of sulfuric acid and hydrogen peroxide), for example, at a temperate above 100° C. As a result of the etching process, portions of fin-shape bases 204 protrude from the recessed isolation structure 230 and the first ILD layer 270 for a distance d. The distance d can be controlled by adjusting duration of the etching process. In some embodiments, the distance d is in a range of about 2 nm to about 15 nm. This range is not arbitrary. As will be explained in further detail below, the distance d approximately defines a thickness of a backside dielectric layer subsequently formed on the protruding sidewalls of fin-shape bases 204 which will remain in the final structure. If the distance d is less than about 2 nm, the subsequently formed backside dielectric layer may be too thin to effectively protect the isolation structure 230 from subsequent backside etching loss. If the distance d is larger than about 15 nm, the subsequently formed backside dielectric layer may be too thick such that the aspect ratio of the subsequently formed backside trench would be too large which makes backside trench filling process difficult.

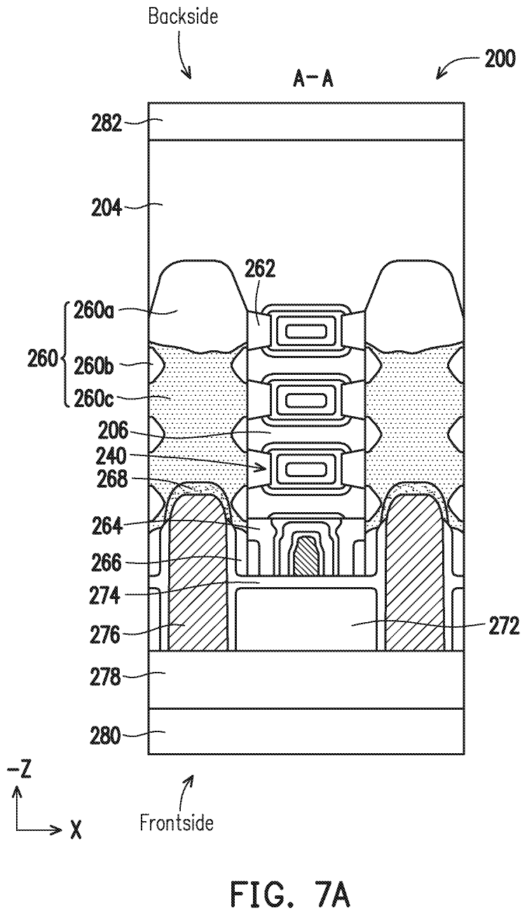

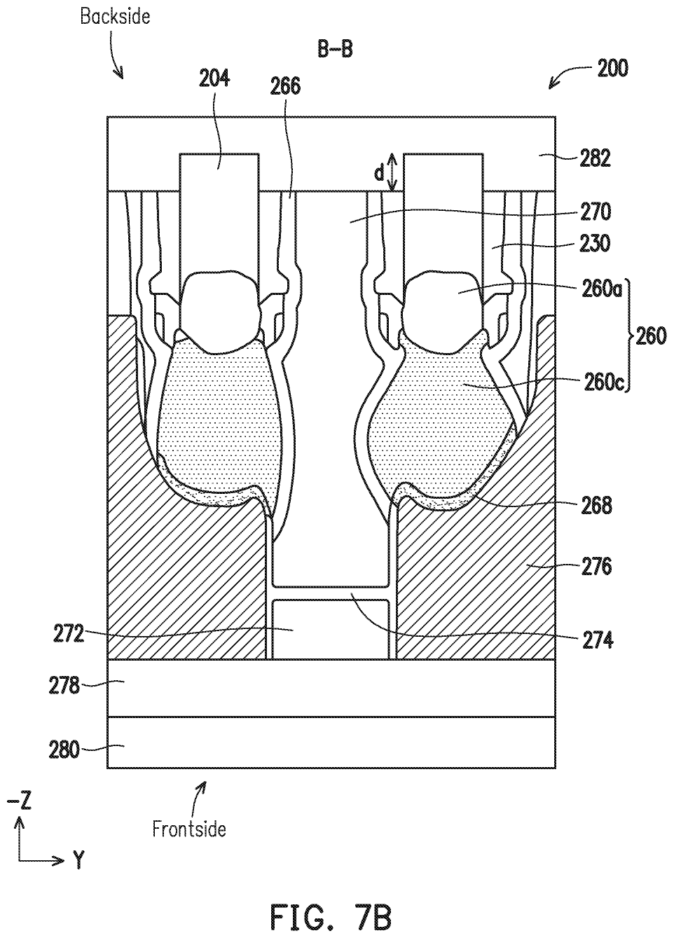

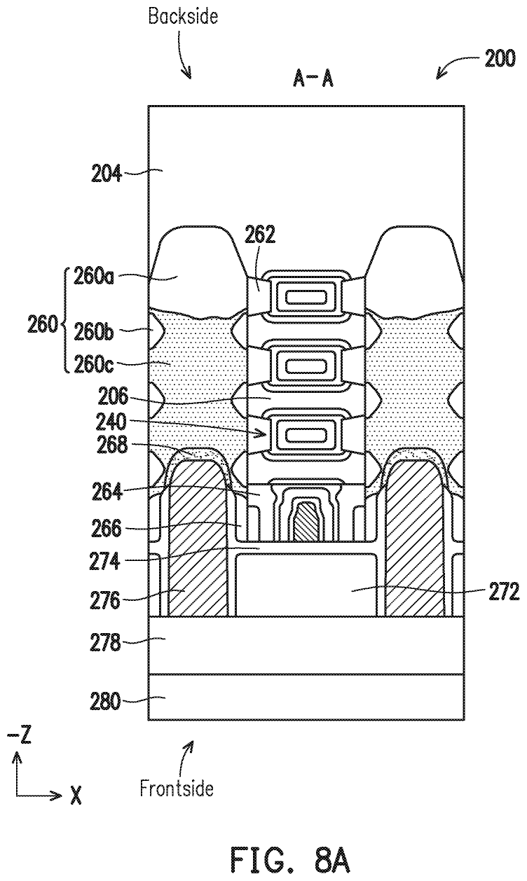

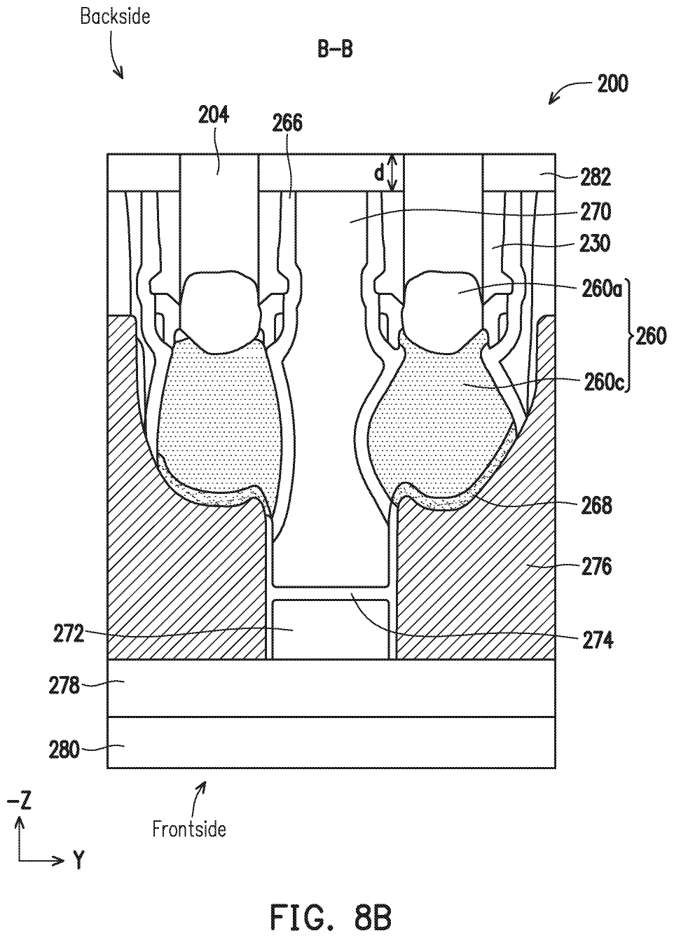

Referring to FIGS. 1 and 7A-7B, at operation 110, the method 100 deposits a backside dielectric layer 282 with one or more dielectric materials to cover the backside of the device 200. In some embodiments, the backside dielectric layer 282 may include metal oxide or metal nitride, such as La₂O₃, Al₂O₃, ZnO, ZrN, Zr₂Al₃O₉, TiO₂, TaO₂, ZrO₂, HfO₂, Si₃N₄, Y₂O₃, AlON, TaCN, other suitable material(s), or combinations thereof. In some embodiments, the backside dielectric layer 282 may include SiOCN, SiOC, SiCN, SiO₂, SiC, ZrSi, other suitable material(s), or combinations thereof. The backside dielectric layer 282 may be formed by PE-CVD. F-CVD or other suitable methods. Further, in the present embodiment, the backside dielectric layer 282 and the isolation structure 230 include different materials so that the backside dielectric layer 282 may act as an etch hard mask to protect the isolation structure 230 from subsequent etching loss. Therefore, the backside dielectric layer 282 may also be referred to as a backside hard mask layer 282. After the deposition of the backside dielectric layer 282, the backside of the device 200 is planarized by the CMP process to expose the bottom surface of the fin-shape bases 204. In other words, the backside dielectric layer 282 is deposited on sidewalls of the protruding portions of the fin-shape bases 204. The resultant structure after the CMP process is shown in FIGS. 8A-8B.

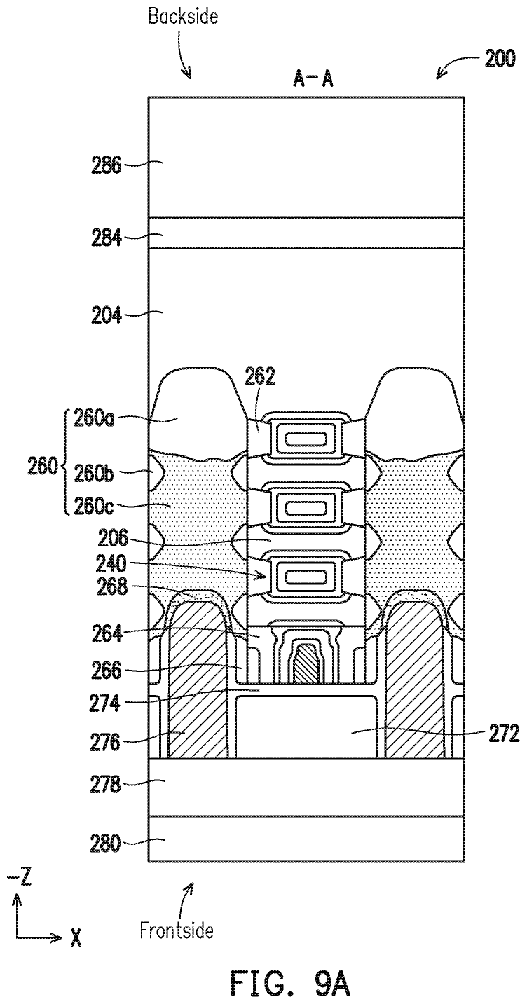

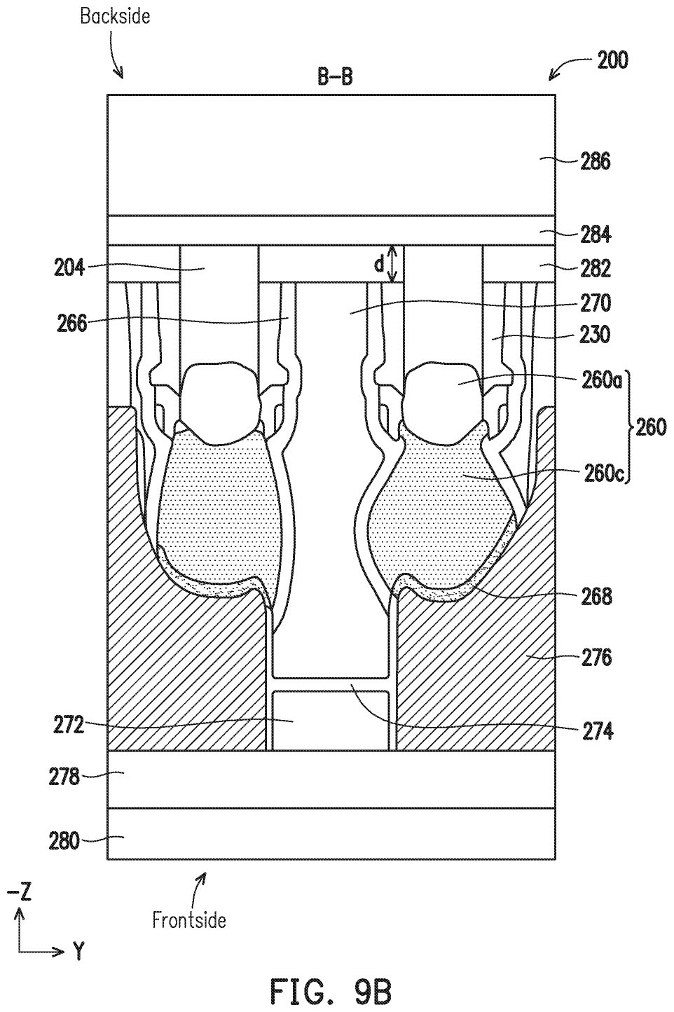

Referring to FIGS. 1 and 9A-9B, at operation 112, the method 100 forms an etch stop layer 284 over the backside of the device 200 and a hard mask layer 286 over the etch stop layer 284. The etch stop layer 284 may be formed of a dielectric material having a different etch selectivity from the backside dielectric layer 282. The etch stop layer 284 may comprise silicon nitride, silicon carbon nitride, silicon carbon oxide, carbon nitride, the like, or a combination thereof. A thickness of the etch stop layer 284 may range from about 5 nm to about 15 nm. The hard mask layer 286 may include SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other suitable materials. A thickness of the hard mask layer 286 may range from about 15 nm to about 45 nm.

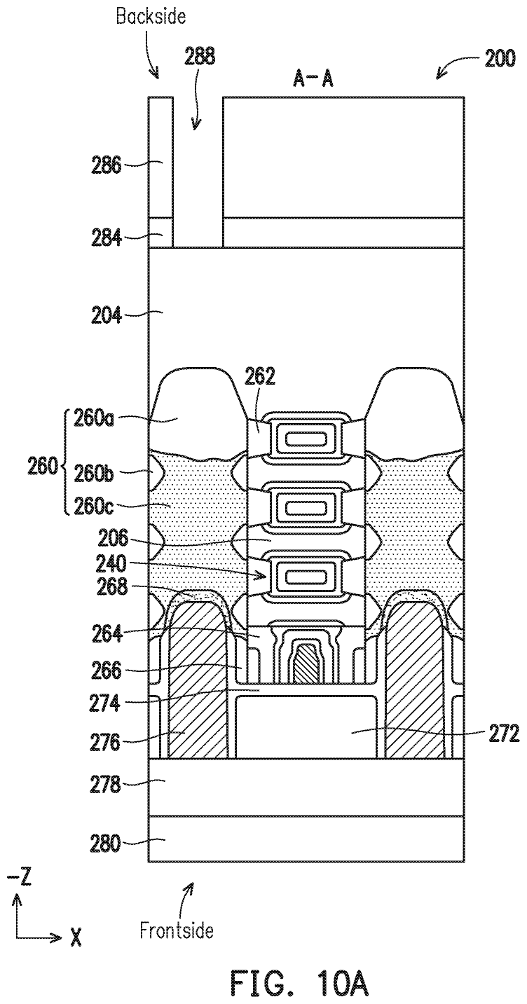

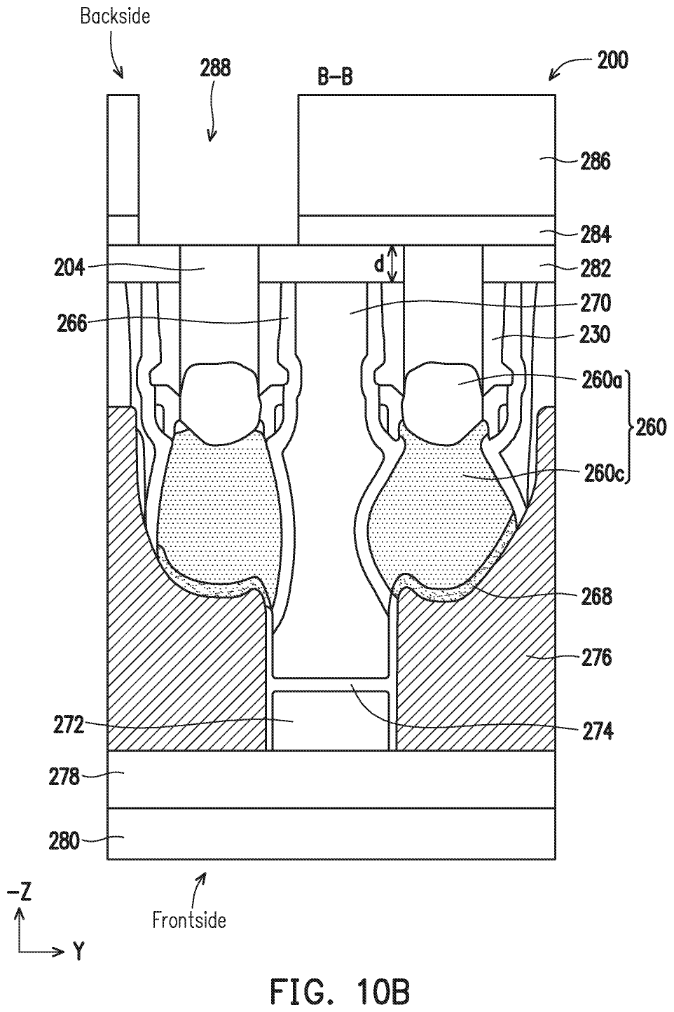

Referring to FIGS. 1 and 10A-10B, at operation 114, the method 100 performs a lithography patterning and etching process to pattern the hard mask layer 286. Particularly, the lithography process forms a patterned photoresist layer (not shown) with an opening directly above one of the fin-shape bases 204, and an etching process is applied to transfer the opening to the hard mask layers 286 as the opening 288. The opening 288 also extends through the etch stop layer 284 at the conclusion of the etching process. In the Y-Z plane (FIG. 10B), the opening 288 is wider than the bottom surface of the fin-shape base 204, such that the width of the bottom surface of the fin-shape base 204 along the Y-direction is fully exposed in the opening 288. In some embodiments, the width of the bottom surface of the fin-shape base 204 along the Y-direction is from about 5 nm to about 100 nm, and the width of the opening 288 is about an extra 10 nm to about 20 nm larger. A portion of the backside dielectric layer 282 is also exposed in the opening 288 (FIG. 10B). As will be described in more details later on, the enlarged width of the opening 288 in the etch stop layer 284 allows a subsequently formed backside via to have a larger contact area in electrical coupling with a backside metal line, which reduces contact resistance. The extra width of about 10 nm to about 20 nm is not arbitrary. If the extra width is less than about 10 nm, the contact resistance reduction may be insignificant to meaningfully improve device performance. If the extra width is larger than about 20 nm, the opening may be too close to adjacent features (e.g., nearby other fin-shape bases 204) and limit the process window.

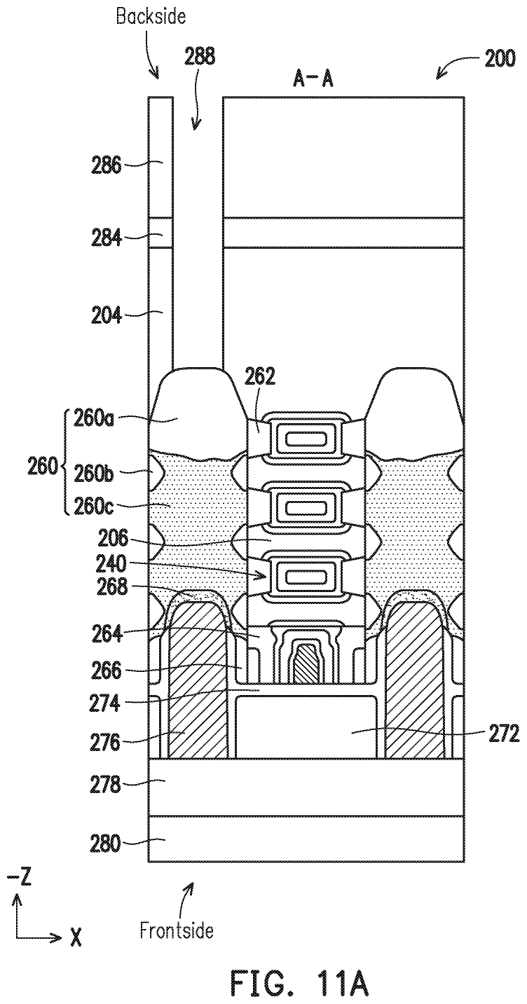

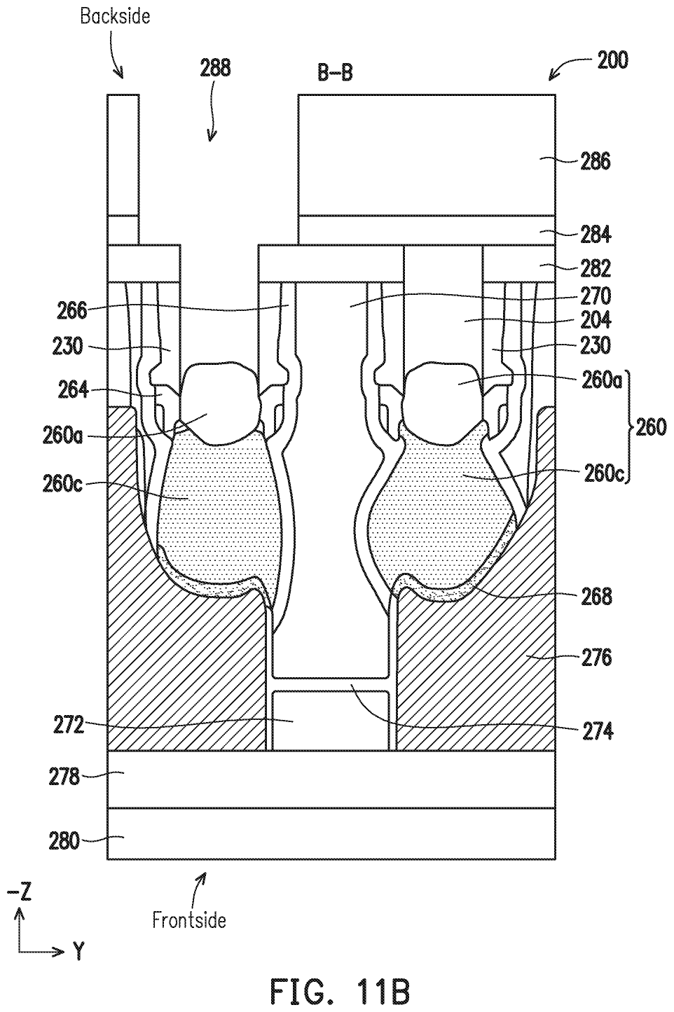

Referring to FIGS. 1 and 11A-11B, at operation 116, the method 100 selectively etches the fin-shape base 204 to extend the opening 288 to the buffer epitaxial layer 260a. The opening 288 is also referred to as the backside trench 288. The backside trench 288 exposes the bottom surface of the buffer epitaxial layer 260a and sidewalls of the isolation structure 230. In some embodiments, the operation 116 applies an etching process that is tuned to be selective to the materials (e.g., Si) in the fin-shape base 204 and with no (or minimal) etching to the backside dielectric layer 282.

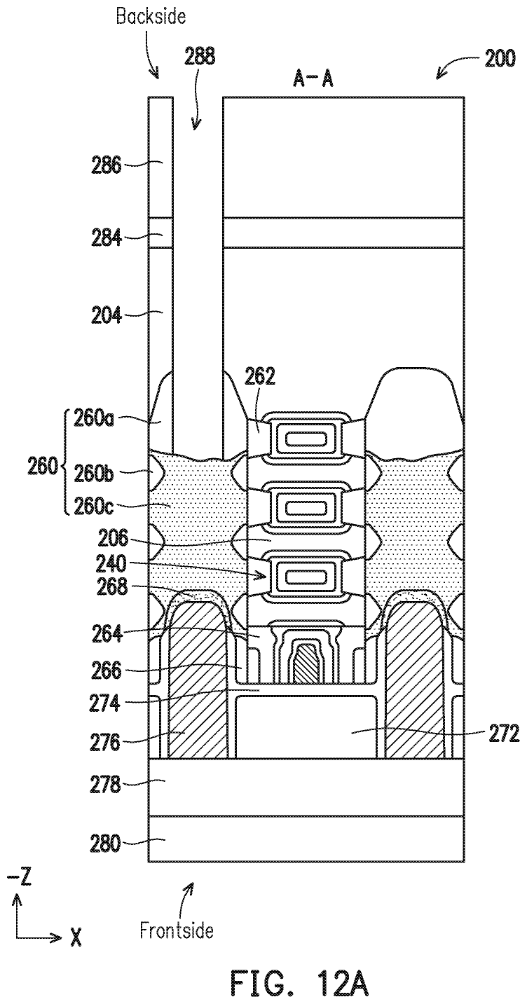

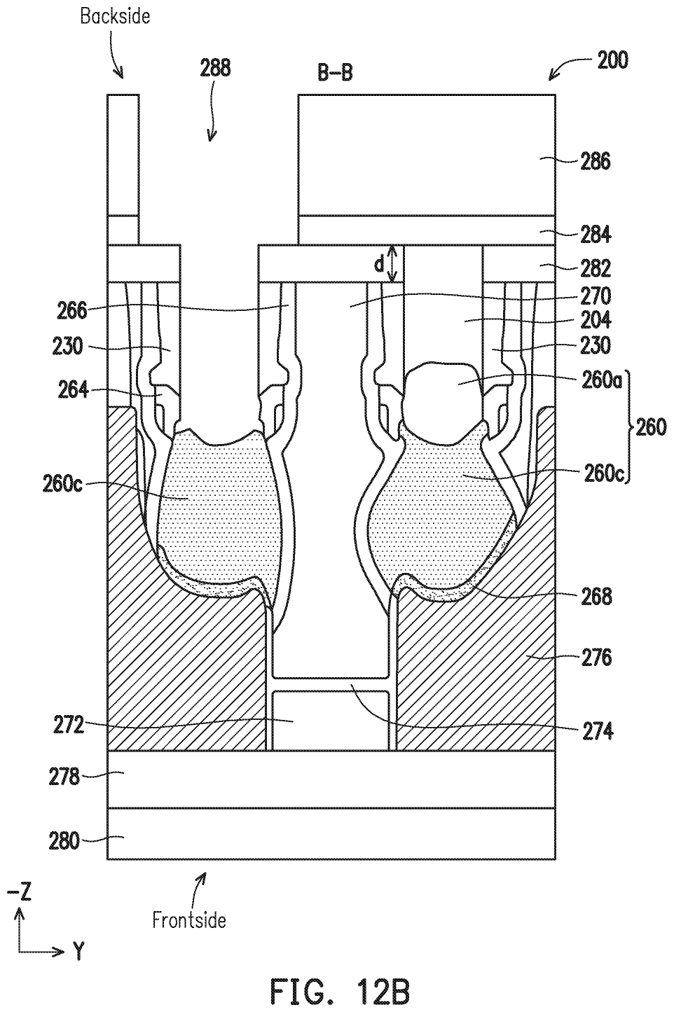

Referring to FIGS. 1 and 12A-12B, at operation 118, the method 100 selectively etches the buffer epitaxial layer 260a to extend the backside trench 288 to the second doped epitaxial layer 260c. The backside trench 288 exposes the bottom surfaces of the second doped epitaxial layer 260c. In the Y-Z plane, the backside trench 288 also exposes sidewalls of the isolation structure 230 (e.g., STI feature and/or DTI feature) and the portion of the gate spacers 264 in the source/drain regions (also referred to as fin spacers). In the X-Z plane, the backside trench 288 extends through the fin-shape base 204 and the buffer epitaxial layer 260a. In some embodiments, the operation 118 applies an etching process that is tuned to be selective to the materials (e.g., SiGe) in the second doped epitaxial layer 260c and with no (or minimal) etching to the backside dielectric layer 282. In some embodiments, as the fin-shape base 204 and the buffer epitaxial layer 260a may include the same semiconductor material (e.g., Si), the selective etching processes performed in operations 116 and 118 may be one etching process. The selective etching processes performed in operations 116 and 118 are not sensitive to position of the upper enlarged portion of the opening 288 and are considered as self-aligned etching processes.

During the etching processes of operations 116 and 118, the bottom surface of the isolation structure 230 remains covered by the backside dielectric layer 282 and substantially remain intact during the etching process. Otherwise, the isolation structure 230 may suffer unneglectable etching loss due to limited etching contrast. If the isolation structure 230 is overly recessed, protruding portions of the gate stack 240 (usually located at regions proximal to the isolation structure 230) may expose from the backside of the device 200 when the covering isolation structure 230 is peeled off, which may cause shorts to nearby conductive features. In the depicted embodiment, since there is substantially no etching loss of the isolation structure 230, protruding portions of the gate stack 240 remains unexposed.

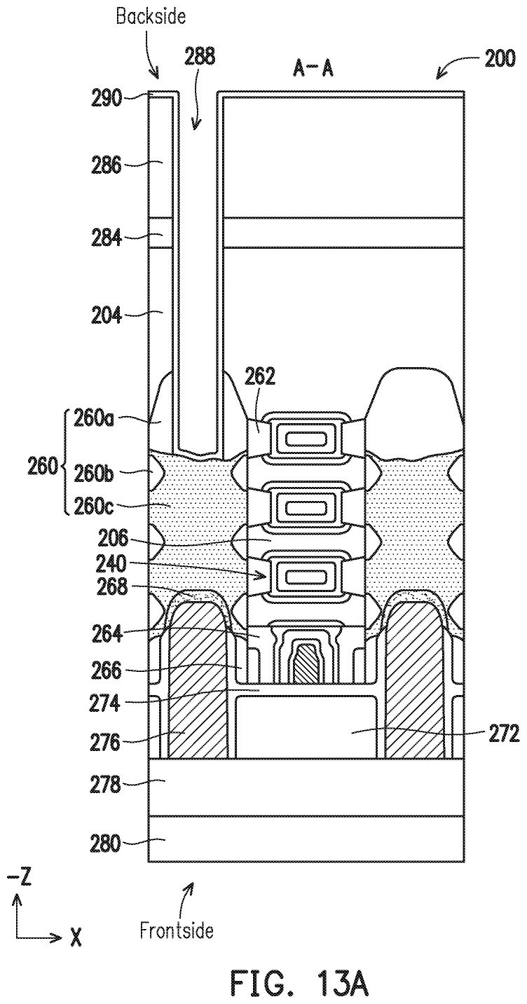

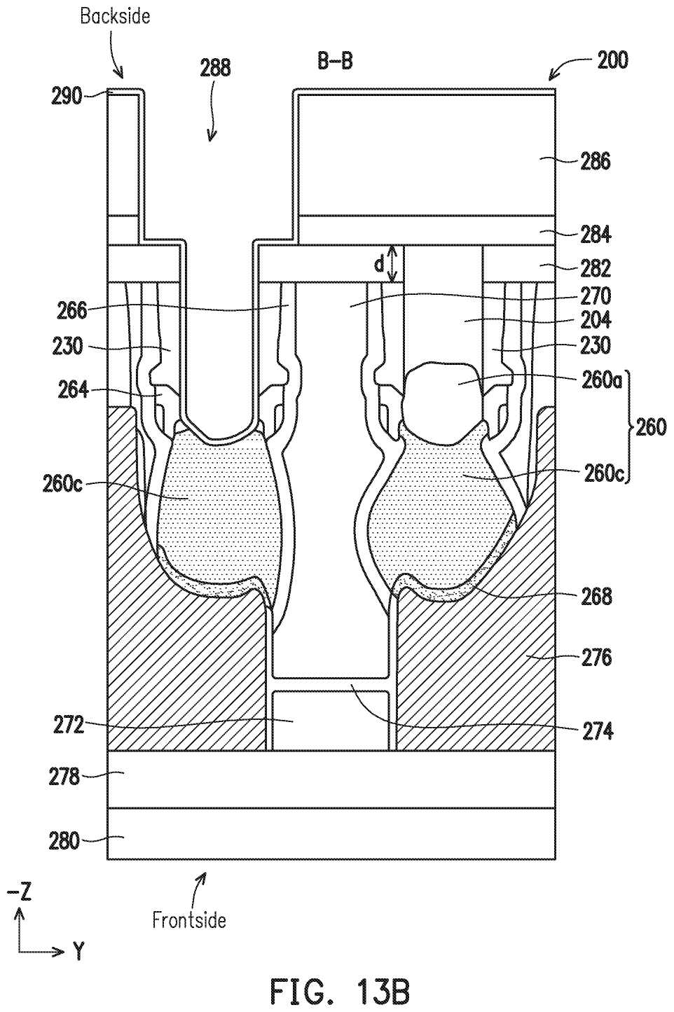

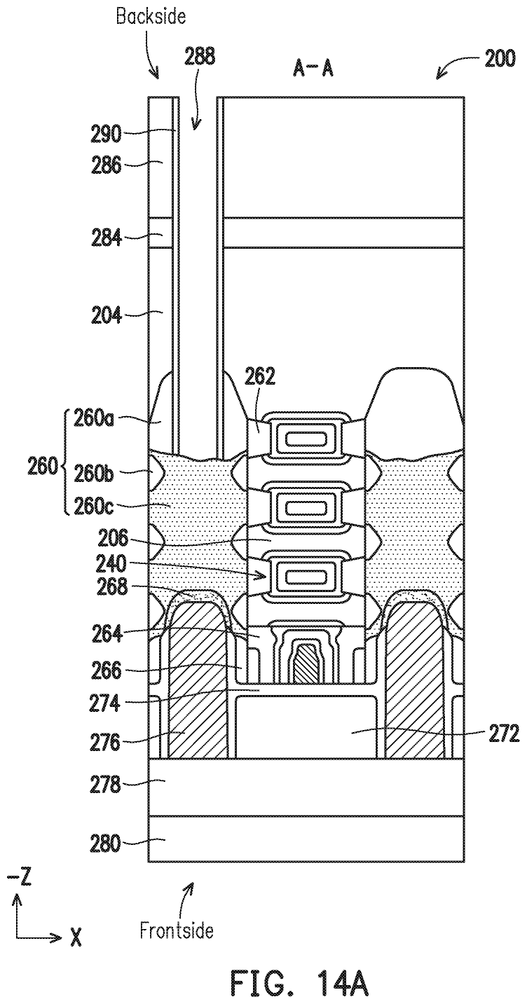

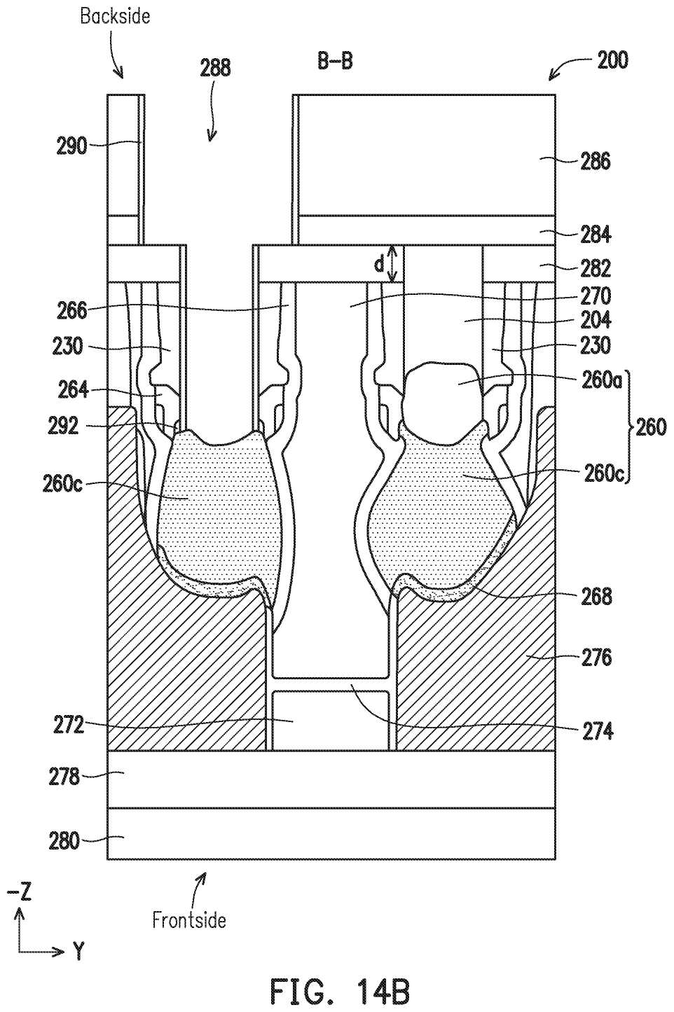

Referring to FIGS. 1 and 13A-13B, at operation 120, the method 100 forms a spacer layer 290 on sidewalls of the backside trench 288. The spacer layer 290 may include a dielectric material such as silicon oxide, silicon nitride, silicon carbide, silicon oxynitride. SiCN films, silicon oxycarbide, SiOCN films, and/or combinations thereof. By way of example, the spacer layer 290 may be formed by blanket depositing a dielectric material layer in a conformal manner over the backside of the device 200 using processes such as, a CVD process, an SACVD process, an ALD process, a PVD process, or other suitable process. In the illustrated embodiment, the deposition of the dielectric material layer is followed by an etching-back (e.g., anisotropically) process to remove the dielectric material layer from horizontal surfaces and expose the bottom surface of the source/drain feature 260 and the bottom surface of the backside dielectric layer 282. The dielectric material layer may remain on the sidewalls of the backside trench 288 as the spacer layer 290. The resultant structure after the etching-back process is shown in FIGS. 14A-14B. In some embodiments, the etching-back process may include a wet etch process, a dry etch process, a multiple-step etch process, and/or a combination thereof. In some embodiments, a thickness of the spacer layer 290 ranges from about 3 nm to about 10 nm. If the thickness of the spacer layer 290 is less than about 3 nm, the spacer layer 290 may be removed during the subsequent cleaning process for forming backside silicide features. If the thickness of the spacer layer 290 is larger than about 10 nm, the spacer layer 290 may become difficult to etch through to expose the source/drain feature 260. In the illustrated embodiment, in the Y-Z plane, the spacer layer 290 may seal voids (also referred to as air pockets) 292 between the gate spacers 264 and the source/drain feature 260.

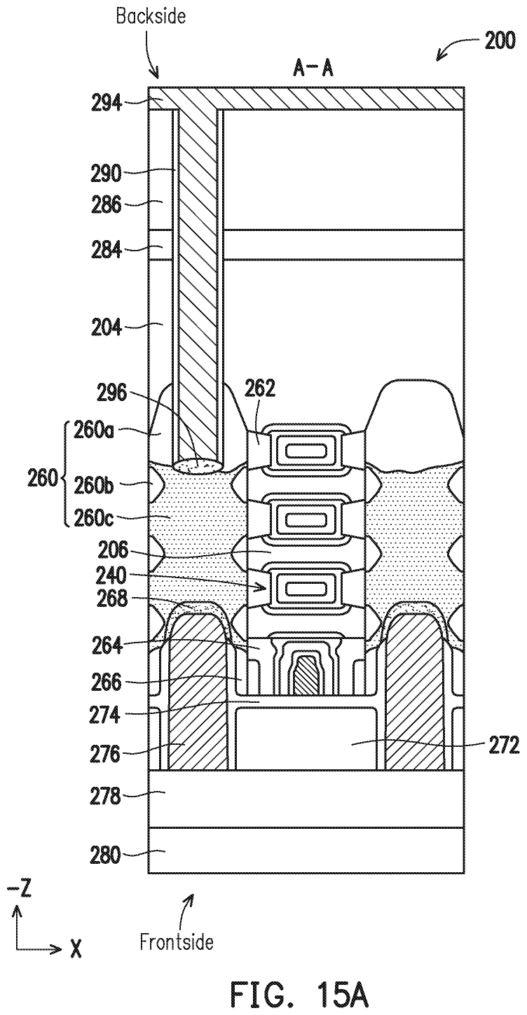

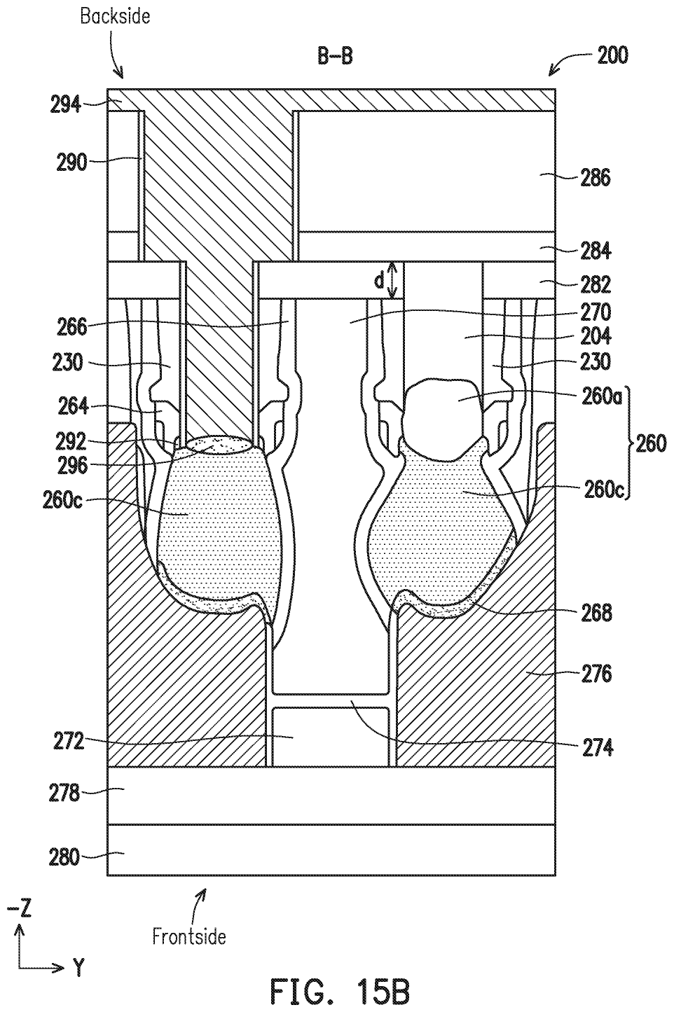

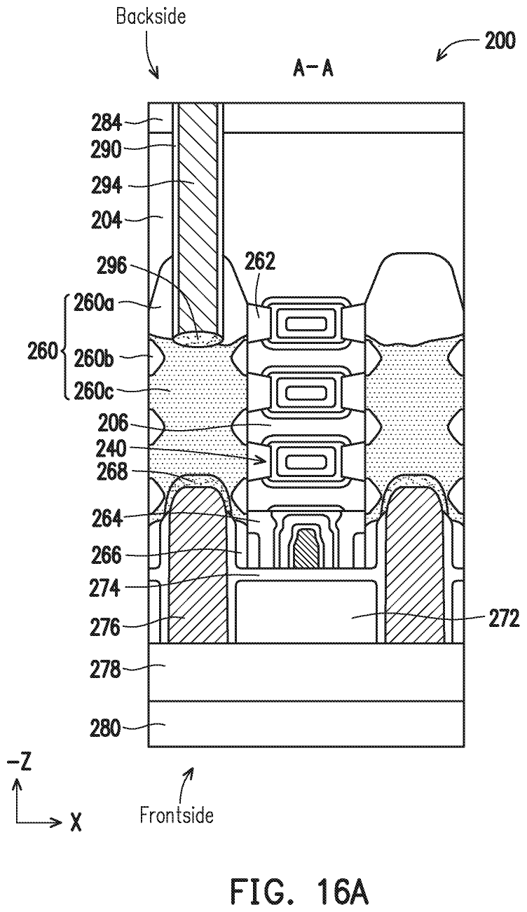

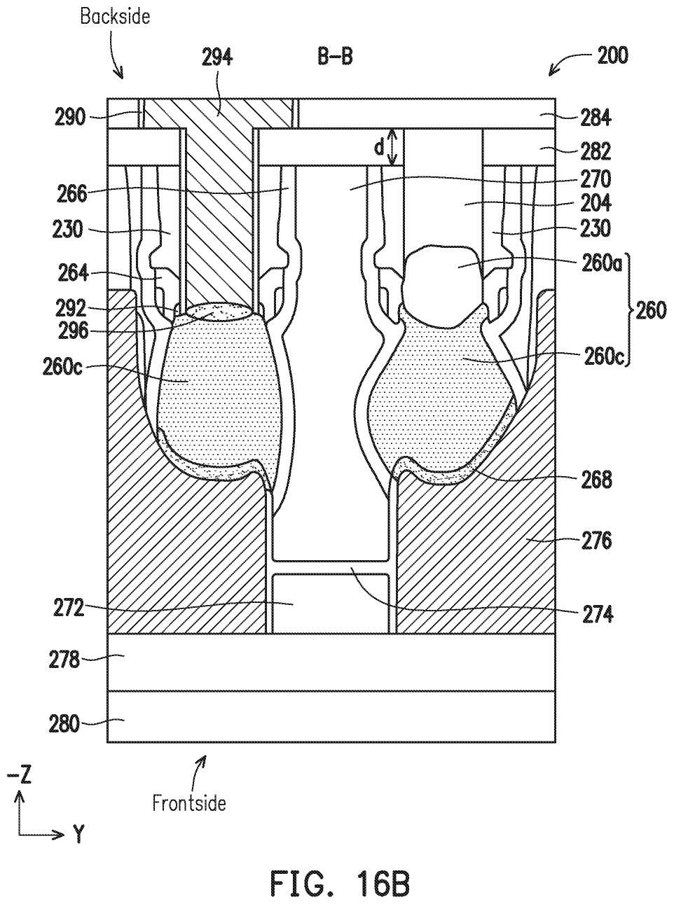

Referring to FIGS. 1 and 15A-15B, at operation 122, the method 100 forms a backside via (or referred to as backside contact) 294 in the backside trench 288. The conductive material of the backside via 294 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD. PVD. ALD, plating, or other suitable processes. The conductive material may cover the backside surface of the device 200. The spacer layer 290 functions as a diffusion barrier layer to prevent the metallic elements in the backside via 294 diffusing into the fin-shape base 204 and surrounding dielectric features, such as the isolation structure (e.g., STI feature and/or DTI feature) 230. In one embodiment, the backside via 294 directly contacts the source/drain epitaxial features 260. Alternatively, in an embodiment, the operation 122 optionally forms a silicide feature 296 between the source/drain epitaxial feature 260 and the backside via 294 to further reduce contact resistance. In furtherance of the embodiment, the operation 122 first deposits one or more metals into the backside trench 288, performing an annealing process to the device 200 to cause reaction between the one or more metals and the second doped epitaxial layer 260c to produce the silicide feature, and removing un-reacted portions of the one or more metals, leaving the silicide feature in the backside trench 288. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD. ALD, or other suitable methods. The silicide feature 296 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. A planarization operation, such as a CMP process, is performed to remove excessive conductive material of the backside via 294. The etch stop layer 284 may function as a stop layer for the planarization operation, such that the planarization operation also removes the hard mask layer 286. The resultant structure after the planarization operation is shown in FIGS. 16A-16B.

Still referring to FIGS. 16A-16B, in the Y-Z plane, the backside via 294 has a pillar portion surrounded by the isolation structure (e.g., STI feature and/or DTI feature) 230 and the backside dielectric layer 282 and a base portion atop the pillar portion and surrounded by the etch stop layer 284. The base portion has a larger width than the pillar portion. The base portion is also in physical contact with the bottom surface of the backside dielectric layer 282. Since the pillar portion is formed by a self-aligned process, even overlying shift occurs during the forming of the opening 288, it is the base portion that may shift slightly to the left or the right of the pillar portion, while the position of the pillar portion won't change, and the isolation structure (e.g., STI feature and/or DTI feature) 230 remains substantially intact. As a comparison, in the X-Z plane, the backside via 294 has substantially straight sidewalls extending from top to bottom.

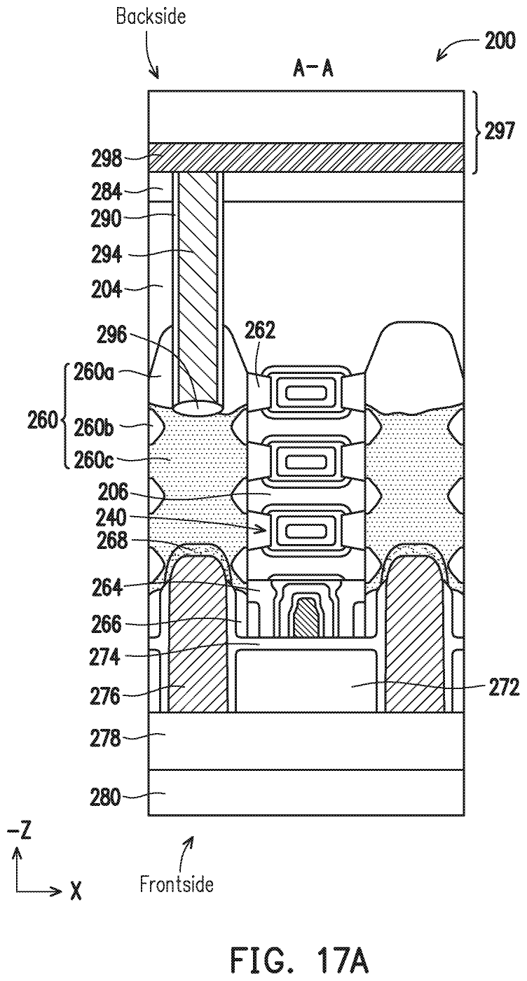

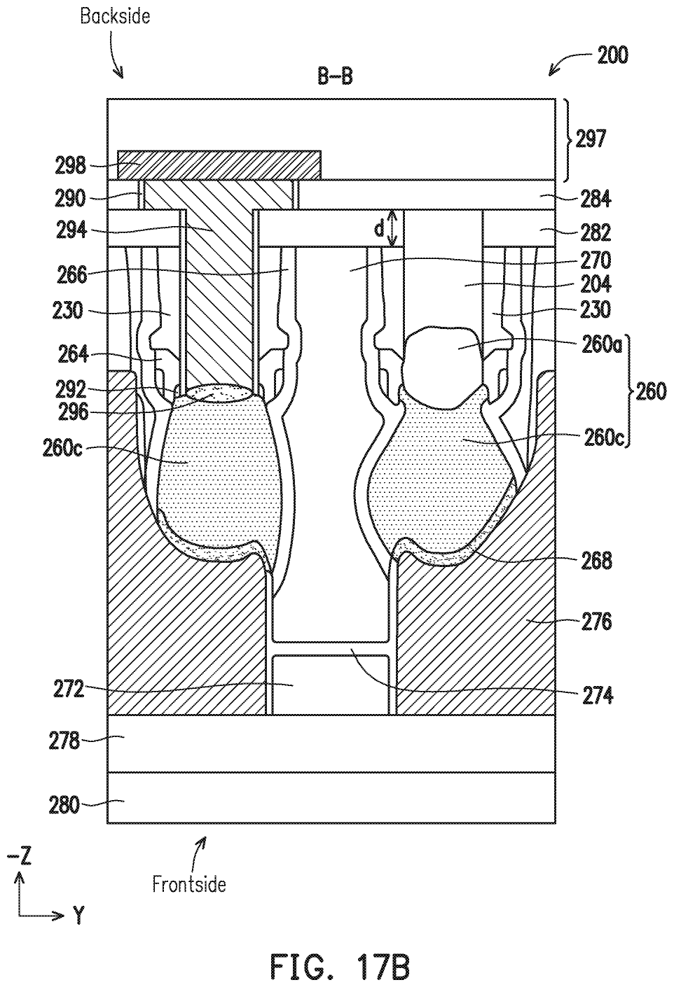

As shown in FIGS. 17A-17B, at operation 124, the method 100 forms one or more backside interconnect layers 297 with backside metal lines, such as the depicted backside metal line 298, embedded in dielectric layers on the backside of the device 200. The backside metal line 298 electrically connects to the source/drain feature 260 through the backside via 294. The enlarged base portion of the backside via 294 reduces contact resistance between the backside metal line 298 and the backside via 294. In an embodiment, the backside metal line 298 may be formed using a damascene process, a dual-damascene process, a metal patterning process, or other suitable processes. The backside metal line 298 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be deposited by CVD, PVD, ALD, plating, or other suitable processes. In some embodiments, the backside metal line 298 is part of the backside power rails. In one example, the source/drain feature 260 in electrical connection with the backside metal line 298 is a source feature of a pull-down transistor in a static random-access memory (SRAM) cell and the backside metal line 298 is an electric grounding line. In another example, the source/drain feature 260 in electrical connection with the backside metal line 298 is a source feature of a pull-up transistor in an SRAM cell and the backside metal line 298 is a power supply line. In some other embodiments, the backside metal line 298 is a signal line and the source/drain feature 260 in electrical connection with the backside metal line 298 is a drain feature of a pull-up or pull-down transistor in an SRAM cell. Although not shown in FIGS. 17A-17B, the backside interconnect layers 297 may include other contacts, vias, wires, and/or other conductive features. Having backside interconnect structures beneficially increases the number of metal tracks available in the device 200 for directly connecting to source/drain features. The backside power rails and/or signal lines may have wider dimension than the first level metal (MO) tracks on the frontside of the device 200, which beneficially reduces the backside power rail resistance.

Although not intended to be limiting, embodiments of the present disclosure provide one or more of the following advantages. For example, embodiments of the present disclosure form a backside via on a semiconductor device's backside in a self-aligned manner. A backside dielectric layer is deposited to cover the isolation structure (e.g., STI feature and/or DTI feature) on the backside of the device to prevent and/or reduce etching loss of the isolation structure, which protects protruding portions of the metal gate stacks from accidently being exposed in the backside of the device. The exemplary process flow also advantageously reserves a relatively larger backside contact area to form interconnect structures with relatively lower contact resistance. Further, embodiments of the present disclosure form backside wiring layers, such as backside power rails and/or backside signal lines, to increase the number of metal tracks available in an integrated circuit and increase the gate density for greater device integration. Embodiments of the present disclosure can be readily integrated into existing semiconductor manufacturing processes.

In one example aspect, the present disclosure is directed to a method. The method includes providing a structure having a frontside and a backside, the structure including a substrate, a fin-shape base protruding from the substrate, an isolation structure on sidewalls of the fin-shape base, an epitaxial feature over the fin-shape base, two or more nanostructures vertically stacked over the fin-shape base and abutting the epitaxial feature, and a gate structure wrapping around each of the nanostructures, the substrate being at the backside of the structure and the gate structure being at the frontside of the structure, recessing the substrate from the backside of the structure to expose a bottom surface of the isolation structure, forming a backside dielectric layer covering the bottom surface of the isolation structure, depositing an etch stop layer on a bottom surface of the backside dielectric layer, forming an opening in the etch stop layer, the opening exposing the fin-shape base from the backside of the structure, etching the fin-shape base from the opening to expose the epitaxial feature, and forming a backside conductive feature in the opening and in physical contact with the epitaxial feature. In some embodiments, the method also includes after the forming of the backside conductive feature, forming a backside interconnect structure on a bottom surface of the etch stop layer, the backside interconnect structure including a backside metal line in physical contact with the backside conductive feature. In some embodiments, the method also includes prior to the forming of the backside dielectric layer, recessing the bottom surface of the isolation structure, such that a bottom portion of the fin-shape base protrudes from the bottom surface of the isolation structure. In some embodiments, the forming of the backside dielectric layer includes depositing a dielectric material covering the bottom surface of the isolation structure and a bottom surface of the fin-shape base, and recessing the dielectric material to expose the bottom surface of the fin-shape base, the recessed dielectric material remaining as the backside dielectric layer. In some embodiments, the backside dielectric layer includes a metal oxide or a metal nitride. In some embodiments, a thickness of the backside dielectric layer ranges from about 2 nm to about 15 nm. In some embodiments, the backside conductive feature includes a pillar portion through the backside dielectric layer and a base portion through the etch stop layer, the base portion being wider than the pillar portion. In some embodiments, the base portion of the backside conductive feature is in physical contact with the bottom surface of the backside dielectric layer. In some embodiments, the epitaxial feature includes a bottom epitaxial layer and a top epitaxial layer, the top epitaxial layer including a dopant concentration higher than the bottom epitaxial layer, the method also includes etching the bottom epitaxial layer from the opening to expose a bottom surface of the top epitaxial layer, the backside conductive feature being in physical contact with the bottom surface of the top epitaxial layer. In some embodiments, the structure includes fin spacers disposed on sidewalls of the epitaxial feature, and the opening exposes the fin spacers.

In another example aspect, the present disclosure is directed to a method. The method includes providing a structure having a frontside and a backside, the structure including a substrate at the backside of the structure and a fin at the frontside of the structure, forming an isolation structure on sidewalls of the fin, epitaxially growing a source/drain feature on the fin, depositing a contact etch stop layer on the source/drain feature, depositing an interlayer dielectric layer on the contact etch stop layer, thinning down the structure from the backside of the structure until the isolation structure is exposed, recessing the isolation structure such that a bottom portion of the fin protrudes from the isolation structure, depositing a backside dielectric layer on sidewalls of the bottom portion of the fin, wherein the backside dielectric layer covers the isolation structure, etching the fin from the backside of the structure to form a backside trench exposing a bottom surface of the source/drain feature, wherein during the etching of the fin the backside dielectric layer remains intact, depositing a conductive feature in the backside trench, and forming a metal wiring layer on the backside of the structure. The metal wiring layer electrically couples to the source/drain feature through the conductive feature. In some embodiments, the thinning down of the structure also exposes the contact etch stop layer from the backside of the structure. In some embodiments, the recessing of the isolation structure also recesses the contact etch stop layer and the interlayer dielectric layer. In some embodiments, the method also includes depositing an etch stop layer under the backside dielectric layer, and forming an opening in the etch stop layer. The opening is wider than the fin and exposes the fin. The depositing of the conductive feature also fills the opening in the etch stop layer, and wherein the metal wiring layer is formed underneath the etch stop layer. In some embodiments, the conductive feature includes a first portion through the isolation structure and a second portion through the etch stop layer. The second portion is wider than the first portion. In some embodiments, the source/drain feature includes an undoped layer and a doped layer. The etching of the fin also etches through the undoped layer of the source/drain feature. In some embodiments, the method also includes prior to the depositing of the conductive feature, forming a spacer layer on sidewalls of the backside trench.

In yet another example aspect, the present disclosure is directed to a semiconductor structure. The semiconductor structure includes first and second source/drain epitaxial features, one or more nanostructures connecting the first and second source/drain epitaxial features, a gate structure engaging the one or more nanostructures. The first and second source/drain epitaxial features, the one or more nanostructures, and the gate structure are at a frontside of the semiconductor structure. The semiconductor structure also includes a metal wiring layer at a backside of the semiconductor structure, a conductive feature directly under the first source/drain epitaxial feature and connecting the metal wiring layer and the first source/drain epitaxial feature, a fin-shape base directly under the second source/drain epitaxial feature, an isolation structure disposed on sidewalls of the fin-shape base and the conductive feature, and a backside dielectric layer covering a bottom surface of the isolation structure. The conductive feature extends through the backside dielectric layer and in physical contact with a bottom surface of the backside dielectric layer. In some embodiments, a thickness of the backside dielectric layer ranges from about 2 nm to about 15 nm. In some embodiments, the backside dielectric layer includes a metal oxide or a metal nitride.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a structure having a frontside and a backside, the structure including a substrate, a fin-shape base protruding from the substrate, an isolation structure on sidewalls of the fin-shape base, an epitaxial feature over the fin-shape base, two or more nanostructures vertically stacked over the fin-shape base and abutting the epitaxial feature, and a gate structure wrapping around each of the nanostructures, wherein the substrate is at the backside of the structure and the gate structure is at the frontside of the structure;
recessing the substrate from the backside of the structure to expose a bottom surface of the isolation structure;
forming a backside dielectric layer covering the bottom surface of the isolation structure;
depositing an etch stop layer on a bottom surface of the backside dielectric layer;
forming an opening in the etch stop layer, wherein the opening exposes the fin-shape base from the backside of the structure;
etching the fin-shape base from the opening to expose the epitaxial feature; and
forming a backside conductive feature in the opening and in physical contact with the epitaxial feature.

2. The method of claim 1, further comprising:
after the forming of the backside conductive feature, forming a backside interconnect structure on a bottom surface of the etch stop layer, wherein the backside interconnect structure includes a backside metal line in physical contact with the backside conductive feature.

3. The method of claim 1, further comprising:
prior to the forming of the backside dielectric layer, recessing the bottom surface of the isolation structure, such that a bottom portion of the fin-shape base protrudes from the bottom surface of the isolation structure.

4. The method of claim 1, wherein the forming of the backside dielectric layer includes:
depositing a dielectric material covering the bottom surface of the isolation structure and a bottom surface of the fin-shape base; and
recessing the dielectric material to expose the bottom surface of the fin-shape base, wherein the recessed dielectric material remains as the backside dielectric layer.

5. The method of claim 1, wherein the backside dielectric layer includes a metal oxide or a metal nitride.

6. The method of claim 1, wherein a thickness of the backside dielectric layer ranges from about 2 nm to about 15 nm.

7. The method of claim 1, wherein the backside conductive feature includes a pillar portion through the backside dielectric layer and a base portion through the etch stop layer, wherein the base portion is wider than the pillar portion.

8. The method of claim 7, wherein the base portion of the backside conductive feature is in physical contact with the bottom surface of the backside dielectric layer.

9. The method of claim 1, wherein the epitaxial feature includes a bottom epitaxial layer and a top epitaxial layer, wherein the top epitaxial layer includes a dopant concentration higher than the bottom epitaxial layer, the method further comprising:
etching the bottom epitaxial layer from the opening to expose a bottom surface of the top epitaxial layer, wherein the backside conductive feature is in physical contact with the bottom surface of the top epitaxial layer.

10. The method of claim 1, wherein the structure includes fin spacers disposed on sidewalls of the epitaxial feature, and wherein the opening exposes the fin spacers.

11. A method, comprising:
providing a structure having a frontside and a backside, the structure including a substrate at the backside of the structure and a fin at the frontside of the structure;
forming an isolation structure on sidewalls of the fin;
epitaxially growing a source/drain feature on the fin;
depositing a contact etch stop layer on the source/drain feature;
depositing an interlayer dielectric layer on the contact etch stop layer;
thinning down the structure from the backside of the structure until the isolation structure is exposed;
recessing the isolation structure such that a bottom portion of the fin protrudes from the isolation structure;
depositing a backside dielectric layer on sidewalls of the bottom portion of the fin, wherein the backside dielectric layer covers the isolation structure;
etching the fin from the backside of the structure to form a backside trench exposing a bottom surface of the source/drain feature, wherein during the etching of the fin the backside dielectric layer remains intact;
depositing a conductive feature in the backside trench; and
forming a metal wiring layer on the backside of the structure, wherein the metal wiring layer electrically couples to the source/drain feature through the conductive feature.

12. The method of claim 11, wherein the thinning down of the structure also exposes the contact etch stop layer from the backside of the structure.

13. The method of claim 11, wherein the recessing of the isolation structure also recesses the contact etch stop layer and the interlayer dielectric layer.

14. The method of claim 11, further comprising:
depositing an etch stop layer under the backside dielectric layer; and
forming an opening in the etch stop layer, wherein the opening is wider than the fin and exposes the fin,
wherein the depositing of the conductive feature also fills the opening in the etch stop layer, and wherein the metal wiring layer is formed underneath the etch stop layer.

15. The method of claim 14, wherein the conductive feature includes a first portion through the isolation structure and a second portion through the etch stop layer, wherein the second portion is wider than the first portion.

16. The method of claim 11, wherein the source/drain feature includes an undoped layer and a doped layer, wherein the etching of the fin also etches through the undoped layer of the source/drain feature.

17. The method of claim 11, further comprising:
prior to the depositing of the conductive feature, forming a spacer layer on sidewalls of the backside trench.

18. A semiconductor structure, comprising:
first and second source/drain epitaxial features;
one or more nanostructures connecting the first and second source/drain epitaxial features;
a gate structure engaging the one or more nanostructures, wherein the first and second source/drain epitaxial features, the one or more nanostructures, and the gate structure are at a frontside of the semiconductor structure;
a metal wiring layer at a backside of the semiconductor structure;
a conductive feature directly under the first source/drain epitaxial feature and connecting the metal wiring layer and the first source/drain epitaxial feature;
a fin-shape base directly under the second source/drain epitaxial feature;
an isolation structure disposed on sidewalls of the fin-shape base and the conductive feature; and
a backside dielectric layer covering a bottom surface of the isolation structure, wherein the conductive feature extends through the backside dielectric layer and in physical contact with a bottom surface of the backside dielectric layer.

19. The semiconductor structure of claim 18, wherein a thickness of the backside dielectric layer ranges from about 2 nm to about 15 nm.

20. The semiconductor structure of claim 18, wherein the backside dielectric layer includes a metal oxide or a metal nitride.
